(19) United States
(12) Patent Application Publication
(10) Pub. No.: US 2010/0040340 A1
(43) Pub. Date: Feb. 18, 2010

(54) Electro-Optic Crystal-Based Structures and Method of Their Fabrication

(75) Inventor: Aharon Agranat, Mevasseret Zion (IL)

Correspondence Address: BROWDY AND NEIMARK, P.L.L.C.;624 NINTH STREET, NW, SUITE 300, WASHINGTON, DC, 20001-5303, US

(73) Assignees: Yissum Research Development Company of the Hebrew; University of Jerusalem, Jerusalem (IL)

(21) Appl. No.: 12/605,014

(22) Filed: Oct. 23, 2009

Related U.S. Application Data
(63) Continuation of application No. 11/911,077, filed on Oct. 9, 2007, now abandoned.
(60) Provisional application No. 60/668,995, filed on Apr. 7, 2005.

(51) Int. Cl. G02B 6/00; G03F 7/20

(52) U.S. Cl. 385/141; 430/321; 385/129; 385/131

(57) ABSTRACT

A structure is presented for use in optic and electro-optic devices. The structure comprises at least one region of an amorphous KLTN-based material in a KLTN-based material. Also provided is a method of processing a KLTN-based material, comprising at least one of the following: bombarding said KLTN-based material with light ions: and etching said KLTN-based material when in amorphous state by an acid; thereby allowing fabrication of one or more optical components within the KLTN-based material.

### FIELD OF THE INVENTION

This invention relates to optical and electro-optical devices and methods of their fabrication.

### REFERENCES

The following references are considered to be pertinent for the purpose of understanding the background of the present invention:
1. J. Y. C. Wong, L. Zhang, G. Kakarantzas, P. D. Townsend, and P. J. Chandler, “Ion-implanted optical waveguides in KTaO₃”, J. Appl. Phys. 71 (1), 49-52, 1 Jan. 1992.
2. D. Fluck, R. Gutmann, and P. Günter, “Optical waveguides in KTa₁₋ₓNbₓO3 produced by He ion implantation”, J. Appl. Phys. 70 (9), 5147-5149, 1 Nov. 1991.
3. F. P. Strohkendl and P. Günter, “Formation of optical waveguides in KNbO₃, by low dose MeV He⁺ implantation”, J. Appt. Phys. 69 (1), 84-88, 1 Jan. 1991.
4. A. J. Agranat, R. Hofmeister and A. Yariv, “Characterization of a New Photorefractive Material: K_{1-y}Li_{y}Ta₁₋ₓNbₓO₃”, Optics Letters 17, 713 (1992).
5. A. J. Agranat, L. Secundo, N. Golshani, and M. Razvag, “Wavelength Selective Photonic Switching in Paraelectric KLTN”, Optical Materials 18 (1) pp. 195-197 (October 2001).
6. R. Hofmeister, S. Yagi, A. Yariv, and A. J. Agranat, “Growth and Characterization of KLTN:Cu, V Photorefractive Crystals”, J. Cryst. Growth 131, pp 486-494 (1993).
7. R Gutmann, J. Hulliger, and E. Reusser, “Liquid phase Epitaxy of lattice matched KTa₁ₓN^{x}O₃ on KTaO₃ substrate”, J. Cryst. Growth 126 (4): 578 -588 (February 1993).
8. M. Sasaura, K. Fujiura, K. Enbutsu, T. Imai, S. Yagi, T. Kurihara, M. Abe, S. Toyoda, and E. Kubota, “Optical waveguide and method of manufacture”, U.S. patent application Ser. No. 00/72,550 (2003).
9. C. M. Perry, R. R. Hayes, and N. E. Tornberg, in Proceedings of the International Conference on Light Scattering in Solids, M. Balkansky, ed. (Wiley, N.Y., 1975), p. 812.
10. A. J. Agranat, “Optical Lambda-Switching at Telecom Wavelengths Based on Electroholography”, in: IR Holography for Optical Communications—Techniques, Materials and Devices, Pierpaolo Boffi, Davide Piccinin, Maria Chiara Ubaldi (Eds.), (Springer Verlag series on Topics in Applied Physics 2002).
11. A. J. Agranat, V. Leyva, and A. Yariv, ‘Voltage Controlled Photorefractive Effect in Paraelectric KTa₁₋ₓNbₓO₃:Cu, V’, Opt. Lett. 14, 1017 (1989).
12. Y. Silberberg, P. Perlmutter and J. E. Baran, “Digital optical switch”, Appl. Phys. Lett. 51 (16), 1987.
13. D. Kip “Photorefractive waveguides in oxide crystals: fabrication, properties, and applications” Appl. Phys. B 67,131-150 (1998).
14. B. E. Little, et al., “Ultra-compact Si—SiO2 microring resonator optical channel dropping filters,” IEEE Photonics Technology Letters 10, 549-551 (1998).
15. M. K. Chin, et al., “GaAs microcavity channel-dropping filter based on a race-track resonator,” IEEE Photonics Technology Letters 11, 1620-1622 (1999).

### BACKGROUND OF THE INVENTION

Potassium lithium tantalate niobate (KLTN) crystal is an oxygen perovskite that was co-invented by the inventor of the present application [1]. KLTN is an electro-optic crystal having a formula K_{1-y}Li_{y}Ta₁₋ₓNbₓO₃, wherein x is between 0 and 1 and y is between 0.0001 and 0.15. Bulk KLTN crystals can be grown for example by the top seeding solution growth method [6], by the liquid phase epitaxial growth on top of a KLTN substrate [7], by the metalo-organic chemical vapor deposition (MOCVD) on silicon and silicon oxide as well as Alumina and magnesium oxide substrates [8].

In the field of oxygen perovskites ferroelectric crystals, it is known that the phase transition temperature T_{c} of such crystal is strongly affected by the presence of impurities and defects [9]. For example, the replacement of a Ta ion in potassium tantalate niobate (KTN) by an Nb ion will cause a change in T_{c} of magnitude: [symbol] T_{c}≈8.5K/1% per mole of Nb. A similar effect can be achieved by replacing a K ion in KTN by either Li or Na. Here the effect is more dramatic and results in certain cases in [symbol] T_{c}≈50 K/1% per mole of Li [4].

KLTN demonstrates a very strong quadratic electro-optic effect at the paraelectric phase. This effect is given by Δn=−(1/2)nₒ³g_{eff}P², where Δn is the induced birefringence, nₒ is the index of refraction, g_{eff} is the effective (quadratic) electro-optic coefficient, and P is the electric polarization induced by the applied field E. At the paraelectric phase the polarization P is given by P=εₒ(εᵣ−1)E≈εE, where εₒ is the electric permeability, and εᵣ is the relative dielectric constant. Typically nₒ=2.4 and g_{eff}=0.2 C²/m⁴ for KLTN.

The electro-optic effect is driven by the induced polarization. In most cases, lithium niobate and other conventional electro-optic crystals are typically used in a phase where they manifest large spontaneous polarization, e.g. well within the ferroelectric phase. Therefore not much polarization is left to be induced, i.e. the polarization is close to saturation. In KLTN at the paraelectric phase there is no spontaneous polarization so that the external electric field can induce a very large polarization change.

In the case of KLTN, a working temperature of an electro-optical device utilizing the quadratic electro-optic effect can be slightly above the phase transition temperature (it was found that at such temperatures KLTN maintains high optical quality and fast dielectric response time). In KLTN the relative permeability of εᵣ=2·10⁴ can for example be provided. If an electric field E=3·10³ V/cm is then applied to the KLTN crystal, the induced birefringence will be [symbol] n=6·10⁻³. This is roughly two orders of magnitude higher than the induced birefringence obtained in other electro-optic materials, such as LiNbO₃.

Also, it is known that KLTN can be made photorefractive when certain impurities (e.g. Cu, V) are added to it.

KLTN crystal was found to be a chemically inert, non-hygroscopic and stable material, so that it is not expected to manifest gradual deterioration in performance.

### SUMMARY OF THE INVENTION

There is a need in the art in facilitating manufacture of various electro-optical devices in crystals demonstrating a high electro-optic effect. Moreover, there is a need in the art for providing a method for manufacturing complex integrated photonic circuits. Each of the photonic circuits is constructed of a multitude of optical components, electro-optic devices, and photonic devices such as photonic crystals, where in these circuits the devices can operate in unison to perform complex functions of light manipulations.

The present invention solves the above problem by providing a novel device and method of its fabrication utilizing a KLTN-based material. The main idea of the present invention is to provide an optical structure in a KLTN-based material, the structure having one or more amorphous region(s) of refractive index(ices) different from that of the refractive index of the crystalline KLTN-based material. The invention also provides a method of fabrication of this structure. The structure contains at least one region of the amorphous KLTN-based material in the crystalline KLTN-based material.

The inventor has found that the amorphous regions (i.e. regions of the amorphous KLTN-based material) having lower refractive indices can be fabricated by implantation of light ions (such as H³⁰, D⁺, He⁺⁺ carbon, oxygen) at energies of several MeVs into the KLTN-based crystal. Such an implantation allows for creating well defined layer(s) of the amorphous material, having high optical quality and index of refraction typically 5%-10% lower than that of the crystal in which these layers are formed.

The inventor has also found that unlike KTN, where the electro-optic response slows down in the vicinity of the phase transition where the effect is large, in KLTN fast electro-optic response can be obtained while maintaining a large electro-optic effect by increasing the Li concentration.

The optical structure of the present invention can be formed by at least one amorphous region at a certain depth from the surface of a KLTN crystal, thus defining at least one optical element, e.g. a waveguide, at either side of the amorphous region.

The optical structure of the invention can be composed of several, possibly interconnected, amorphous regions distributed at predetermined depths from the KLTN crystal surface, thus forming a multi-layer structure. An arrangement of amorphous regions within each of these layers can be of a different preselected shape as well as of a different pattern, where the pattern is formed by spaced-apart amorphous regions spaced by the crystalline regions. Thus, the structure of the invention can be configured to define complex integrated circuits containing a multitude of optical, electro-optic, and optoelectronic components, for example, waveguides, volume gratings, electroholographic devices, etc. For example, the resulting integrated circuit of optical components interconnected by the waveguide pathways can present (or function as) a micro optical bench. Also, the invention can provide for fabricating photonic band gap crystals in the host KLTN crystal, by creating amorphous regions and then applying an etching (material removal) process to said regions. The photonic band gap crystals can also be included as part of the said complex integrated circuits.

According to the preferred embodiments of the invention, the optical structure is formed by spatially selective amorphization of the volume of a KLTN crystal. The amorphization can be performed by implantation of high energy ions into the preselected region(s) within the KLTN material. The feature size of the bombarded regions can be small (e.g. 200 nm). The resulting refractive index within the bombarded regions can be for example 10% less than that of the host crystal.

There is thus provided according to one broad aspect of the invention, a structure for use in optic and electro-optic devices, the structure comprising at least one region of an amorphous KLTN-based material in a KLTN-based material.

The KLTN-based material may be a KLTN crystal. The amorphous KLTN-based material may be formed by an amorphization of the KLTN-based material. Preferably, the configuration is such that the at least one amorphous region contains a significant amount of Frenkel defects. The amorphous region is formed by bombarding of KLTN-based material with light ions. The bombarding ions may include at least one of the following types: H⁺, D⁺, He⁺⁺, Carbon or Oxygen; and may include ions having kinetic energy larger than 1 MeV.

The amorphous region of the amorphous KLTN material can be buried inside the KLTN-based material.

In some embodiments of the invention, the structure includes a plurality of the amorphous regions of the amorphous KLTN-based material arranged to form a single patterned layer. This layer may be planar.

The multiple regions of the amorphous KLTN-based material can be used being arranged in at least two patterned layers, accommodated at different depths from a surface of the KLTN-based material.

The region of the amorphous KLTN-based material may define a waveguide in KLTN-based material at either side of the amorphous region. This waveguide may be arranged to substantially confine light in one dimension or in two dimensions; as well as may be arranged to allow propagation of light of a single mode.

The region of amorphous KLTN-based material may be configured to define a ring resonator, or a closed loop region of the crystalline KLTN based material forming the resonator. The resonator may be operable as a tunable electro-optic resonator.

The amorphous region may be patterned to define an electroholographic alpha grating; or an electro-optic modulator in a waveguided configuration; or at least one cross bar switch constructed as an array of multilevel ring resonators in which the input and output waveguides are orthogonal to each other and are constructed above and below the rings respectively.

The structure is formed with an electrode arrangement for applying electric field to at least one predetermined region thereof. The electrode arrangement includes at least one buried electrode.

According to another broad aspect of the invention, there is provided a structure for use in optic and electro-optic devices, the structure comprising a KLTN-based material patterned to form a photonic crystal. The photonic crystal may be a 1D, 2D or 3D photonic crystal.

According to yet another aspect of the invention, there is provided a method of processing of a KLTN-based material, the method comprising at least one of the following: (a) bombarding said KLTN-based material with light ions; (b) etching said KLTN-based material when in amorphous state by an acid; thereby allowing fabrication of one or more optical components within the KLTN-based material.

According to yet another aspect of the invention, there is provided a method of processing a KLTN-based material, the method comprising bombarding said KLTN-based material with light ions and etching the KLTN-based material when in amorphous state, resulted by said bombarding, by an acid such as a mixture of HF and HNO₃.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1A exemplifies an optical structure according to the invention configured to define a waveguide in KLTN; specifically this structure is a slab waveguide in which the core is the crystalline material immediately beneath the surface of the crystal below where there is a cladding layer implemented in amorphous material fabricated by the implantation process;

FIG. 1B shows a distribution of the refractive index at some wavelength within the structure of FIG. 1A;

FIG. 2A shows a cross-section of an optical structure according to another example of the invention, obtained utilizing a stopping mask that enables to fabricate a channel waveguide, demonstrating the general method for fabricating structures with lateral features;

FIGS. 2B and 2C show the experimental and theoretical data for a change in a refractive index resulted from annealing;

FIG. 3 illustrates a dependence of the refractive index on depth within a structure of the invention;

FIG. 4 shows a structure according to yet another example of the invention, configured to define an “in-depth” Bragg grating;

FIG. 5 exemplifies a structure of the invention configured to define a multilevel electro-optic ring resonator;

FIGS. 6A and 6B there is exemplified a structure configured as an electroholographic switch;

FIG. 7 exemplifies a structure configured as an alpha grating, namely, a volume grating constructed by creating a periodic modulation of the index of refraction through the process of selective implantation;

FIG. 8 illustrates a dependence of the refractive index on depth within a structure of the invention for the structure obtained by implantation of two layers of C ions; and

FIG. 9 shows a photo of the experimental structure of the invention obtained by implantation of two layers of C ions.

### DETAILED DESCRIPTION OF EXEMPLARY EMBODIMENTS

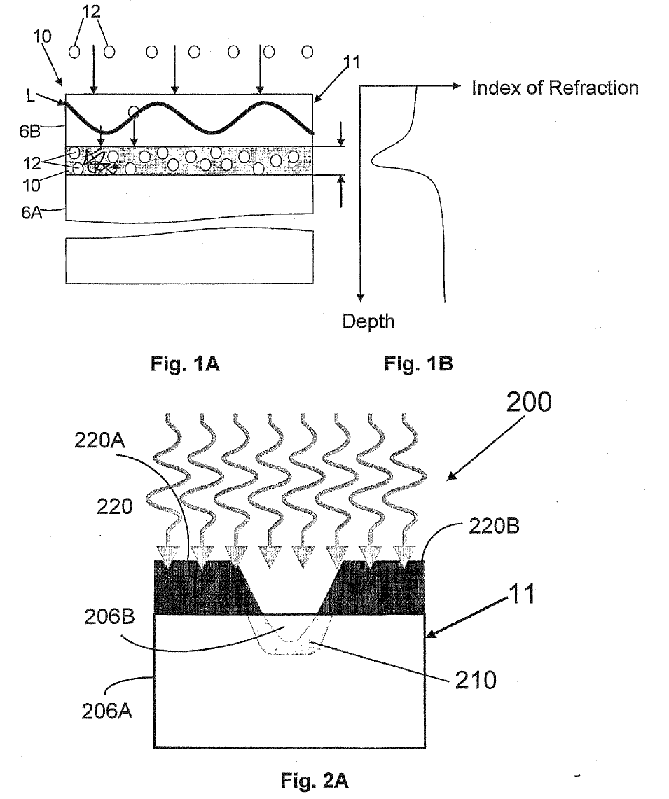

Referring to FIG. 1A, there is shown an example of an optical structure 100 of the present invention for use in optic and electro-optic devices. Structure 100 includes a region 10 of an amorphous KLTN-based material, enclosed between lower and upper regions 6A and 6B of a crystalline KLTN-based material 11. In the present example, amorphous region 10 and crystalline region 6B are designed to have refractive indices and thicknesses enabling effective waveguiding propagation) of a beam L of some light wavelength(s) and polarization(s) along region 6B. Amorphous region 10 presents a boundary (cladding) defining a waveguide region 6B enclosed between said cladding and the upper surface of structure 100 serving as the opposite boundary.

Amorphous region 10 is formed by implantation of light ions, generally at 12, into the KLTN substrate 11. Regions (layers) 6A and 6B are portions of the substrate separated by layer 10 resulted from the implantation. Interfaces between layers 6A and 10, and 6B and 10 are well defined because of the peculiarities (mechanism) of the interaction between fast ions 12 and the crystal medium 11.

There are two main mechanisms for the interaction between a medium and a penetrating ion. The first mechanism—the so-called electronic stopping—is stronger while the velocity of the ion penetrating the bombarded material is high (be the ion an α-particle, or a proton, or a deuterium nucleus, a carbon ion, an oxygen ion, etc.). According to this mechanism, the moving ion interacts almost exclusively with the electronic clouds that surround the heavy ions of the lattice. Thus, initially the bombarding ion traverses the crystal without diverting from its original direction. At this electronic stopping phase, the propagation of the ion into the material can be described as a movement under friction causing the propagating ion to gradually slow down.

At low velocities of the moving ion, its cross section for scattering by the lattice ions increases dramatically. The propagating ion tears a lattice ion from its site in the lattice unit cell, causing the lattice ion to become an interstitial ion at a different site. This interaction mechanism between a medium and the penetrating ion is called nuclear stopping. At the nuclear stopping phase, bombarding ions generate Frenkel defects.

It was found by the inventor that if a significant amount of Frenkel defects is created in some region of KLTN, this region will become partially amorphous. Such a partially amorphous Frenkel defects containing region has an index of refraction that is lower by up to 10% than the index of refraction of the host crystal. The depth at which the amorphized region is located within the crystal is mostly determined by the initial energy of the implanted ions. The thickness of the amorphized layer is mostly determined by the dosage of the implantation.

It should be noted, although not specifically shown in FIG. 1A, that the bombardment of a KLTN crystal can be done through a stopping mask. The latter can be constituted for example by a possibly patterned metal layer deposited on top of the KLTN substrate surface. Implantation through such a mask causes the implantation pattern and consequently the formed amorphous layer to be determined by the geometry of the mask.

The Transport of Ions in Matter (TRIM) simulations performed by the inventor indicate that a flat stopping mask of a 3 μm thick gold can be used for constructing planar 2D amorphous region 10 at a depth of 5 μm below the surface of the KLTN crystal by bombarding the KLTN crystal by alpha-particles of kinetic energies of 2.24 MeV.

Referring to FIG. 1B there is schematically shown distribution of the refractive index at some wavelength within structure 100. It is seen that the refractive index is low in region 10 of structure 100. Also, the refractive index in region 6B is slightly lower than in region 6A, non accessible to bombarding ions.

Structure 100 thus defines a waveguide, wherein buried planar region 10 serves as a cladding layer. In the present example, the waveguiding effect is obtained in layer 6B, but it could be obtained in layer 6A, or in both layers 6A and 6B. Thus, region 10 of the amorphous KLTN-based material defines at least one waveguide in KLTN-based material 11 at either side of the amorphous region. This waveguide is arranged to substantially confine light in the vertical dimension.

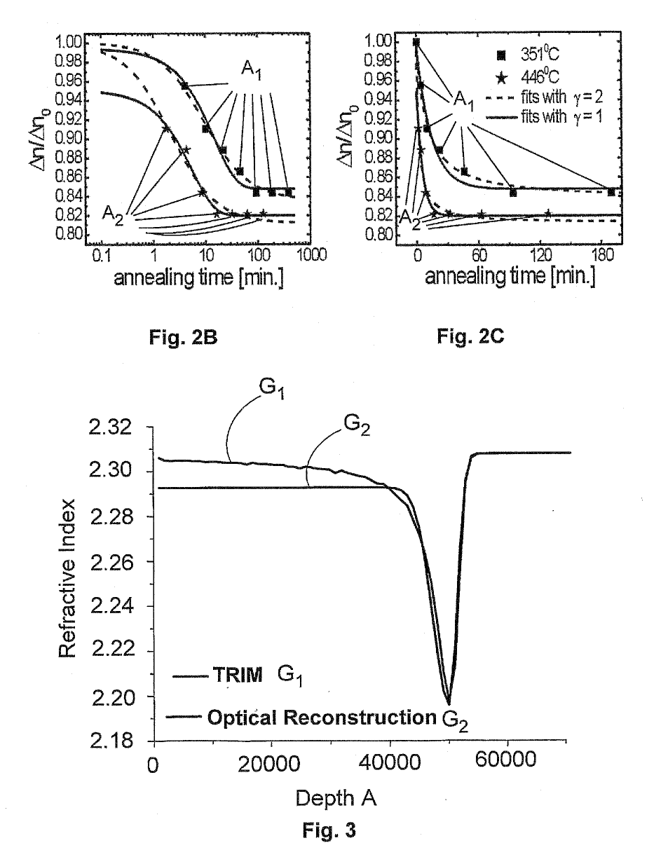

Referring to FIG. 2A, there is shown a cross-section of an optical structure 200 according to another example of the invention. Structure 200 contains KLTN layers 206A and 206B and an amorphous layer 210. Structure 200 is configured so as to enable waveguiding of light of one or more predetermined wavelength(s) and polarization(s) in layer 206B. Amorphous cladding layer 210 of waveguide 206B is non-planar and is arranged to substantially confine the light in the vertical and horizontal dimensions. Thus, in waveguide 206B light propagates perpendicular to the shown cross-section of structure 200. Parameters of waveguide 206B can be selected so as to allow propagation of various modes and polarizations, e.g. of a single mode.

Non-planar amorphous layer 210 is created by implantation of light ions into a KLTN substrate material 11. While the implantation was performed, the surface of structure 200 was protected with a stopping mask 220. Mask 220 had a non-uniform thickness and could be made for example of gold. As the light ions had not passed through thicker regions 220A and 220B of the mask, no amorphous regions were formed beneath these mask regions. The profile of layer 210 repeats the thickness profile of mask 220: layer 210 is closer to the surface of structure 200 where the mask was thicker. Thus implantation of the light ions into KLTN utilizing the stopping mask allows for creating patterned amorphous layers within the host crystal. Following the implantation process the stopping mask can be removed from the substrate.

Within the framework of the stopping mask method, each mask is designed and fabricated so as to allow for generating a desired lateral and vertical distribution of defects. The propagation of the bombarding ions through the mask can be simulated for example by Transport of Ions in Matter (TRIM) program employing Monte Carlo calculations. For example, the TRIM simulations performed by the inventor have shown that a golden stopping mask of a 3 μm thickness and having a 6 μm wide trench can be used for constructing a planar 2D amorphous region encapsulating a core of crystalline material with a trapezoidal cross section with its wide base at the surface of the crystal having width of 6 μm, and its small base at a depth of 5 μm below the surface of the KLTN crystal (the implanted particles are alpha-particles of energy 2.24 MeV). The trench is produced by standard lithographic and wet etch process applied to the gold layer. The selected aspect ratio of the trench walls enabled waveguide fabrication in a single implantation session.

Thus, in the experiment performed by the inventor, the fabricated waveguiding layer 6B of FIG. 1A was approximately 5 μm thick and cladding layer 10 was 0.5 μm thick (the implanted dose of alpha-particles was 1.1·10¹⁶ cm⁻²). Following the implantation, the profile of the refractive index within the waveguide was extracted by measuring the light coupled into the waveguide as a function of the coupling angle. The measurements were done using a prism coupling setup. The results of experimentally measured refractive index will be described further below with reference to FIG. 3. A measurement of the insertion loss yielded α_{WG}=0.1 dB/cm for λ=1.3 μm, i.e. a fairly small loss. It should be noted that this result is affected by the quality of the polishing of the crystal surface and can be improved.

After the implantation, two samples of the structure of FIG. 1A were annealed: the first at 351° C. and the second at 446° C. for repeated periods of time. At the end of each period, the refractive index profile of structure 10 was measured. The respective results (change in refractive index—isothermal annealing data A₁ and A₂) are shown in FIG. 2B in a logarithmic time scale and FIG. 2C in a linear time scale

Also, two theoretical models were built to explain experimental data A₁ and A₂. Two approximations according to the two theoretical models are graphed for each set of data A₁ and A₂ by solid and dashed lines. The models used are described below.

The overall change in the refractive index change of the implanted layer [symbol] nₒ is proportional to the overall density C₀ of the defects generated by the implantation. Some of these defects are annihilated during the annealing phase, so that the relative change in the refractive index caused by the annealing process is given by:

$$\frac{Δ n ( t ) {\vert}_{T}}{Δ {n}_{o}} = \frac{C ( t ) {\vert}_{T}}{{C}_{o}} \qquad ( 1 )$$

where C(t)|_{T} and [symbol] n(t)|_{T} are the defects concentration, and the change in the index of refraction after annealing at temperature T for a time period t.

The kinetics of the defects concentration for defects with activation energy Eₐ is given by

$$\begin{matrix}\frac{d C}{d t} = - {KC}^{γ} & ( 2 a ) \\ K = {K}_{o} exp ( - \frac{{E}_{a}}{{k}_{B} T} ) & ( 2 b )\end{matrix}$$

where γ is the dimension of the process, and K is the isothermal constant.

For an annealing process involving interstitial defects and vacancies that are equally mobile it should be assumed that γ=2. Allowing the annealing process to converge to a constant value the following equation is obtained:

$$\frac{Δ n ( t ) {\vert}_{T}}{Δ {n}_{o}} = \frac{1 - α}{1 - ( 1 - α ) K ( t - {t}_{o} )} + a \\ ( γ = 2 ) \qquad ( 3 )$$

where a is the value to which [symbol] n(t)/ [symbol] nₒ converge asymptotically as t→∞.

If the mobilities of the vacancies and interstitials differ drastically, γ=1 should be assumed. In this case:

$$\frac{Δ n ( t ) {\vert}_{T}}{Δ {n}_{o}} = ( 1 - α ) exp [ - K ( t - {t}_{o} ) ] + a \\ ( γ = 1 ) \qquad ( 4 )$$

In practice γ is between 1 and 2. It should be noted that in both (3) and (4) annealing at a temperature T does not affect defects for which the activation energy is substantially higher than k_{B}T.

Both models were fitted to the experimental data and are presented in FIGS. 2B and 2C (solid and dashed lines). The activation energies that gave the best fit were Eₐ=0.6 eV for γ=2, and Eₐ=0.4 eV for γ=1. Both models fit the data with the same level of accuracy. Hence, the value of the activation energy for the relaxation of the Frenkel defects should be taken to be Eₐ=0.5±0.1 eV. In any event, annealing at 350° C. for three hours stabilizes the waveguide for all temperatures below 350° C.

Thus, it has been found by the inventor, that the waveguide was stabilized with 1-2 hours of annealing. The thermal stability of the annealed waveguide was tested by keeping the waveguide for 2 weeks at 150° C. The annealed waveguide was found to be completely stable, that is the index profile remained completely unchanged.

Turning back to FIG. 2A, it should be noted that in structure 200 amorphous layer 210 may be patterned to define not 1D-waveguide 206B, but a volumetric element, e.g. resonator. In this case, layer 210 protrudes to the surface of structure 200 in cross-sections in front and beyond the cross-section shown. The respective stopping mask has an opening that is not a trench, but a rectangle. The dimensions of the resonator can be set to enable realization of the resonance condition for light of some predetermined wavelength.

It should be noted that the fabrication of an arbitrary volumetric element may require exposing the substrate to a series of consecutive implantations processes with different energies and different stopping masks.

Referring to FIG. 3, there are shown graphs G₁ and G₂ of a dependence of the refractive index on depth within a structure of the invention. Graph G₁ is a theoretical refraction index profile that was reconstructed by the inventor from a TRIM simulation of the implantation process, and graph G₂ is an experimental index profile that was extracted from the optical measurements. Both graphs G₁ and G₂ have a negative peak at depth of 5000 Å corresponding to an amorphous region. FIG. 3 corresponds to the refractive index distribution before the annealing.

It should be noted that the model used to derive the refractive index profile from the modes profile measured directly using the prism coupler system assumes a core with a uniform refractive index, and hence the difference between the TRIM simulation and the experimental results both manifested in FIG. 3.

It is seen that since the TRIM simulation program yields accurate prediction of the distribution of the defects and implants, the reconstruction of refractive index based on thus simulated defect distribution is an effective tool in the structure design.

However, it should be noted, that the simulations performed by the inventor indicate that the thickness of the defect region depends on the initial energy of the ions, so that the thickness and depth are not independent parameters. However, the ratio between the width and depth depends strongly on the type of the implanted ion. When the heavier ions (Carbon and Oxygen) were used the ratio of width of the implanted layer to its depth was smaller.

Preferably, this interdependency of the thickness and depth is taken into account during the planning of an implantation session. An iterative process of repeated implantations of various ions at different energies and doses may be used and in some cases even required to generate an arbitrary predetermined refraction index distribution and thus to define the optical structure.

It should also be noted that the simulations performed by the inventor indicate that the amorphous layer expands relatively to the crystalline material. For instance, in the lateral dimension this expansion was of approximately 200 nm in the first few microns below the surface for experiments of implanting alpha particles 5 μm deep into the crystal as was derived from the Trim simulation). The lateral dimension expansion depends on the type of implanted ion and the ion energy. Preferably, this expansion is taken into account when the implanted ion is selected and a stopping mask is designed for producing a desired pattern of the index of refraction. The stopping mask method applied to KLTN enables construction of integrated circuits and structures of arbitrary architecture and minimum feature size of at least 200 nm.

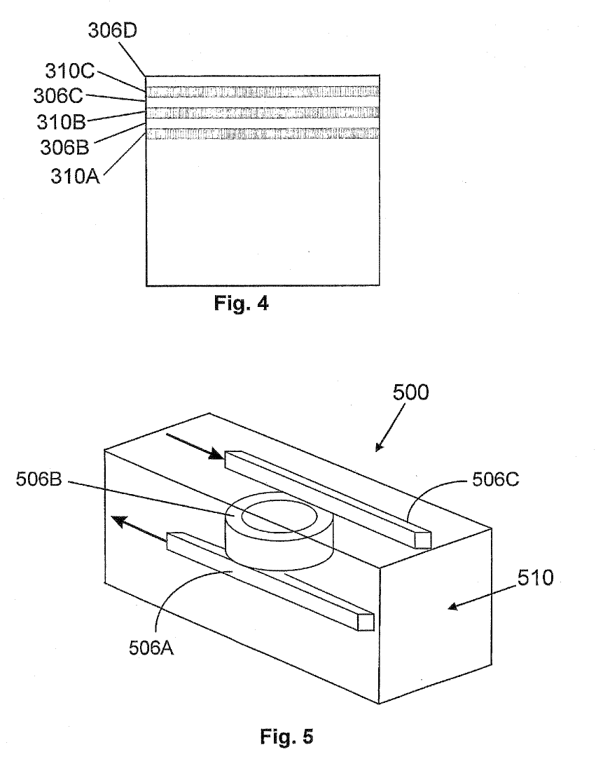

Referring to FIG. 4 there is shown a structure 300 according to yet another example of the invention. Structure 300 contains three amorphous layers 310A, 310B and 310C and four KLTN layers 306A-306D. Structure 300 can be used for waveguiding of light through layers 306A-306D.

The three amorphous layers are created by implantation of light ions of different energies: the higher the energy of the bombarding ions, the deeper lies the respective amorphous layer. Each amorphous layer can be patterned in accordance with a pattern of the respective stopping mask protecting the KLTN crystal from the implantation (however, the patterns are not shown in this figure).

On the other hand, structure 300 presents an example of the “in depth” Bragg grating. The “in depth” Bragg grating is a 1D grating with a grating vector that is perpendicular to the substrate surface. The grating is constructed of alternating layers of crystalline and amorphous material regions. In case an “in depth” grating has just a few layers, it will demonstrate Raman-Nath diffraction.

Referring to FIG. 5 there is exemplified a structure 500 of the invention configured to define a multilevel electro-optic closed loop resonator (ring resonator) constituted by a region 506B of the KLTN crystalline material. Structure 500 also includes two waveguides 506A and 506C in proximity of resonator 506B serving as the input and output of the resonator. Ring 506B and waveguides 506A and 506C are embedded into amorphous region 510 (and defined by it). The latter is created by amorphization of the KLTN substrate by implantation of light ions through the respective stopping masks. The types, doses and energies of the implants as well as the number of the implantation sessions are determined according to the required geometrical and optical parameters of structure 500.

Closed loop resonator 500 fabricated by thus described method of the refractive index engineering is advantageous over other resonators of the same type, because it can be easily tuned by the application of the external electric field to the crystalline KLTN material. The fact that the electro-optic effect in KLTN is fast and very large gives to KLTN-implemented devices a wide range of tunability at fast response rates. Moreover, the fact that the input and output waveguides can be placed above, below or at the same level as the ring resonator, allows design of complex optical and electro-optical circuits containing multiple possibly interconnected ring resonators, for example arranged in a cross-bar switch.

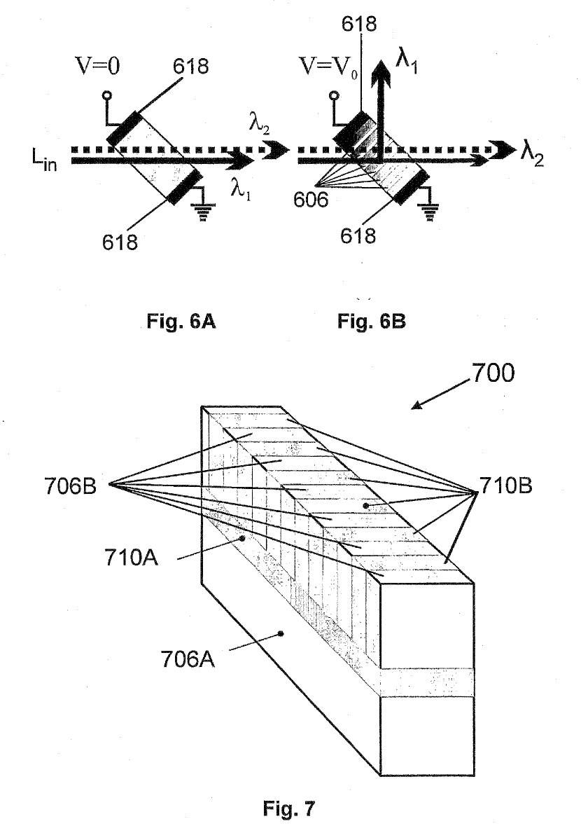

Referring to FIGS. 6A and 6B, there is exemplified a structure 600 configured as an electrically controlled Bragg grating of a different type. Structure 600 has regions 606A and 606B of a KLTN-based material of different Curie temperatures. The spatial modulation of the Curie temperature can be realized either by using the appropriate stopping mask to produce alternating regions of crystalline material and amorphous material, as described below with reference to FIG. 7. Alternatively it can be realized by using the alpha grating structure of FIG. 7, etching away the amorphous regions, and then regrowing crystalline material into the empty trenches with different ratio of Li/K and/or Nb/Ta. Structure 600 also has electrodes, generally at 618, for application of electric field (voltage difference) to the grating. The electrodes can be buried.

At the paraelectric phase, the dielectric constant is given by the Curie law, and a spatial modulation of the composition between regions 606A and 606B causes a spatial modulation δT_{c}(x) in the Curie temperature.

This modulation in the Curie temperature causes a modulation in the dielectric constant given by

$$δ ɛ ( x ) = - \frac{C}{{( T - {T}_{c} )}^{2 }} \cdot δ {T}_{c} ( x ) \qquad ( 5 )$$

where εᵣ is the relative static or low frequency dielectric constant, C is the Curie-Weiss constant, and Tis the temperature. It was assumed in (5) that δT_{C}<<T_{c}.

Applying a uniform electric field E to structure 600 generates a modulation in the induced polarization given by

δP(x)=δε(x)E (6)

where it is assumed that the crystal is slightly above the Curie temperature T_{c} so that εᵣ>>1.

Due to the quadratic electro-optic effect, the spatially modulated polarization induces modulation of the birefringence:

$$\begin{matrix}δ [ Δ n ] ( x ) = - {n}_{o}^{3} {g}_{eff .} P \cdot δ P \\ = - {n}_{o}^{3} {g}_{eff .} ɛ \frac{δ {T}_{c} ( x )}{T - {T}_{c}} {E}^{2}\end{matrix} \qquad ( 7 )$$

Thus, the induced birefringence is governed by the applied electric field. Also, this birefringence is zero (dormant) at zero electric field.

Bragg grating 600 can be used for example for electroholography, i.e. a wavelength selective optical switching method based on governing the reconstruction process of volume holograms by means of an electric field [10]. In addition, the applied field governs the efficiency of the reconstruction. As explained in detail in reference [10], arrays of electroholographic switches enable the performing of different wavelength selective light manipulation operations such as grouping, multicasting, power management and non-intrusive data monitoring as an integral part of the switching operation.

When the electric field is off, as in FIG. 6A, the grating is in its latent state. In this state, the grating is transparent so that the incident beam propagates through the grating unaffected. When the electric field is on (FIG. 6B), the grating is activated. In the ‘on’ (active) state, those wavelengths of an input beam Lᵢₙ will be diffracted that fulfill the Bragg condition. In FIG. 6B, beam at wavelength λ₁ is diffracted. The wavelengths of input beam Lᵢₙ that do not fulfill the Bragg condition will propagate through active grating 600 unaffected, as wavelength λ₂ in FIG. 6B. Thus, the electrically controlled grating 600 possesses the basic features for functioning as a wavelength selective switch or a power distributor.

Referring to FIG. 7 there is exemplified a structure 700 configured as an electroholographic alpha grating. Grating 700 has a KLTN crystalline region 706A (substrate), a lateral amorphous region 710A, and several vertical crystalline regions 706B interlaced with several amorphous regions 710B. Lateral amorphous region 710A defines a waveguide for light propagating through a sequence of regions 706B and 710B. Thus, the electroholographic alpha grating is an electrically controlled dielectric electro-optic grating constructed in a waveguide configuration. In the reflective configuration, the alpha grating functions as a narrow filter with a wide range of tunability due to the large electro-optic effect in KLTN.

The alpha grating can be fabricated for example by selective etching of amorphous material 710B and subsequent regrowth of crystalline material in thus created trenches. It is known that KLTN and other derivatives of potassium tantalate in crystalline form are resistant to the conventional etching methods, because these crystals are closely packed due to the size of the potassium ion. The inventor has found that the amorphous KLTN is more easily etched by various acids (such as a mixture of HF and HNO₃). Thus the selective etching can be used to partially or fully etch out amorphous regions 710B while leaving crystalline regions 706B intact. It should be noted, that as such the grating will become a 1D photonic crystal.

After the etch, a liquid phase epitaxy re-growth of crystalline material can be performed to fill the trenches created in place of amorphous regions 710B. The composition of the KLTN that will be grown into the trenches can contain a different ratio of Nb/Ta and Li/K so that a spatial modulation of the Curie temperature will be formed. Thus, an electroholographic grating with zero diffraction at zero applied field will be produced

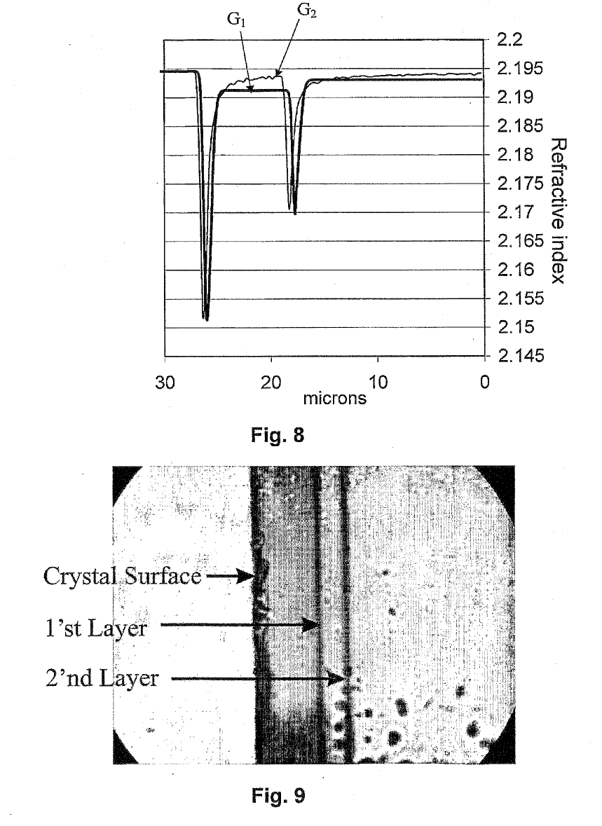

Referring to FIG. 8 there is shown the refractive index distribution obtained by implantation of Carbon-12 ions into KLTN. Graph G1 corresponds to the experimental results derived from a direct measurement of the modes profile; graph G2 follows from TRIM simulation. It is seen, that two layers of partially amorphous material were generated by the implantation.

The two layers were implanted consecutively with energies of 30 MeVs and 40 Mevs respectively. This yielded two layers at approximately 18.5 microns and 26.5 microns below the surface respectively. In these experiments the implantation dosage was approximately 0.6·10¹⁵ ions/cm² which yielded a relative index change of 2%.

In FIG. 9 a picture of the crystal illuminated from below is shown. The implanted layers are darker than other KLTN.

Also, the inventor performed experiments with Oxygen-16 ions. In these experiments oxygen-16 ions were implanted with energy of 30 MeVs with dosage of 2·10¹⁵ ions/cm². That yielded a layer at approximately 12 μm below the surface of the crystal with a relative index change of 8%. For comparison the alpha particle implantations were with a dosage of 10¹⁶ ions/cm², which yielded a layer with a relative index change of 4%. In both cases increasing the dosage caused damage to the crystals.

Besides increasing the depth of implantation, an additional advantage of using Oxygen and Carbon layers was the ability to produce layers with a smaller width. This is especially important in waveguides that are embedded well below the surface as the width of the implanted layer is approximately proportional to the depth of the implantation.

A variety of KLTN-based optical devices can be fabricated by implantation of light ions, lithography, etching including Reactive Ion Etching, metallization, and electro-plating. Thus designed optoelectronic devices can perform wavelength selective switching, electro-optic phase and intensity modulation, spectral filtering for the visible and near IR spectral ranges.

Thus, the present invention provides a KLTN-based structure containing at least one region of an amorphous KLTN-based material in a KLTN-based material. The structure can be configured to define various optical, electro-optical and optoelectronic devices. The invention also provides for a method of fabrication of such devices.

Those skilled in the art will readily appreciate that various modifications and changes can be applied to the embodiments of the invention as hereinbefore described without departing from its scope defined in and by the appended claims.

1. A structure for use in optic and electro-optic devices, the structure comprising amorphous KLTN-based material regions in a KLTN-crystal, said amorphous regions being buried inside the KTLN-crystal and laterally and vertically distributed in said KLTN-crystal in the form of a complex multi-layer structure comprising an arrangement of the amorphous regions within each layer having a preselected shape and predetermined pattern which is formed by spaced-apart amorphous regions, such as to define one or more optical devices.

2. The structure of claim 1, wherein at least some of the amorphous regions have different refractive indices being different from a refractive index of the KLTN-crystal.

3. The structure of claim 1, wherein the arrangement of said amorphous regions define a predetermined refractive index distribution within the KLTN-crystal.

4. The structure of claim 1, wherein said amorphous regions are arranged to form complex integrated photonic circuits interconnected by waveguide pathways, the complex integrated photonic circuits defining a plurality of optical components to perform complex functions of light manipulations.

5. The structure of claim 1, wherein the arrangement of the amorphous regions define at least one volumetric optical component.

6. The structure of claim 1, comprising a plurality of the regions of said amorphous KLTN-based material arranged in at least two patterned layers, accommodated at different depths from the surface of said KLTN-crystal.

7. The structure of claim 1, wherein said complex structure comprises one or more waveguides arranged to substantially confine light in one and/or two dimensions.

8. The structure of claim 1, wherein said complex structure comprises one or more waveguides, at least one of the waveguides being arranged to allow propagation of light of a single mode.

9. The structure of claim 1, wherein said at least one optical device includes at least one of an electro-optic device, a modulator, a resonator, a volume grating, an electroholographic device, a cross bar switch, a waveguide.

10. The structure of claim 9, wherein said at least one cross bar switch is constructed as an array of multilevel ring resonators in which input and output waveguides are orthogonal to each other and are located at different layers above, below or above and below the rings.

11. The structure of claim 1, wherein said KLTN-crystal is patterned to form at least one photonic crystal being a 1D, 2D or 3D photonic crystal.

12. A structure for use in optic and electro-optic devices, the structure comprising a plurality of regions of an amorphous KLTN-based material arranged in at least two patterned layers, accommodated in a KTLN-crystal at different depths from a surface of said KLTN-based material.

13. A structure for use in optic and electro-optic devices, the structure comprising amorphous KLTN-based material regions in a KLTN-crystal, at least some of the amorphous regions having different refractive indices being different from a refractive index of the KLTN-based material.

14. A method of fabricating the structure of claim 1, the method comprising applying a refractive index engineering to the KLTN-based material by bombarding said KLTN-crystal with light ions, said bombarding being performed through a patterned ion stopping mask thereby forming a corresponding pattern of the amorphous regions buried inside the KLTN-crystal, thereby allowing fabrication of one or more optical components within the KLTN-crystal.

15. The method of claim 14, wherein said bombarding is performed with ions of various kinetic energy ranges, the ions thereby stopping at various depths presenting the stopping mask.

16. The method of claim 14, wherein said pattern in the ion stopping mask is in the form of the mask regions of different thicknesses.

17. The method of claim 14, comprising applying a selective etching by acid of a region of said KLTN-based material when in amorphous state in KLTN-crystal resulted from said bombarding.

18. The method of claim 17, wherein the selective etching comprises etching by a mixture of HF and HNO₃.
